(19) United States
(12) Patent Application Publication
(10) Pub. No.: US 2010/0123249 A1
(43) Pub. Date: May 20, 2010

(54) SEMICONDUCTOR DEVICE AND METHOD OF MANUFACTURING SEMICONDUCTOR DEVICE

(75) Inventor: Koichi MOTOYAMA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/548,460

(22) Filed: Aug. 27, 2009

(30) Foreign Application Priority Data
Nov. 17, 2008 (JP) 2008-292909

(51) Int. Cl. H01L 23/532; H01L 21/768; C23C 14/34

(52) U.S. Cl. 257/751; 438/653; 204/298.13; 257/E23.161; 257/E21.584

(57) ABSTRACT

A semiconductor device includes an insulating film, a trench which is formed in the insulating film, a barrier metal film which is formed on a sidewall and a bottom surface of the trench, and is composed of an alloy of titanium (Ti) and tantalum (Ta), and a copper (Cu) wiring which is stacked on the barrier metal film, and located in the trench. A titanium concentration of the barrier metal film is equal to or more than 0.1 at % and equal to or less than 14 at %.

This application is based on Japanese patent application NO. 2008-292909, the content of which is incorporated hereinto by reference.

### BACKGROUND

1. Technical Field

The present invention relates to a semiconductor device, a method of manufacturing a semiconductor device, and a target for manufacturing a semiconductor device.

2. Related Art

In an LSI (Large Scale Integration) wiring, a Cu wiring is used. Since Cu easily diffuses into an insulating film, a barrier metal film is formed in a wiring trench before forming the Cu wiring. In this way, it is possible to prevent Cu from diffusing into an insulating layer or a substrate. As the barrier metal film, an alloy of tantalum (Ta) and titanium (Ti) is generally used.

In Japanese Laid-open patent publication NO. 2003-109956, a configuration where a ratio of Ti in a barrier metal film is equal to or more than 15 at % and equal to or less than 90 at % is described. As a result, resistance and stress of the barrier metal film that is used in the Cu wiring can be reduced.

In Japanese Laid-open patent publication NO. 2001-110751, a configuration is described, in which a peripheral portion of an insulating film has a high Ti concentration and a peripheral portion of a Cu film has a high Ta concentration, thereby giving a gradient to the Ti concentration. As a result, the insulating film and the Cu film are effectively used together with copper and other conductor materials, and easily adhere to oxides and other thin dielectric films, and low distortion or a heteroepitaxial relationship is generated while a boundary is formed.

Due to a decrease in the size of a transistor, wire resistance of a Cu wiring greatly increases. The reason is as follows. If a Ti concentration is excessively high, a large amount of Ti diffuses into the Cu wiring by a heat history, which results in increase in the wire resistance. Further, since Ti is an element that is lighter than Ta, a coating rate (coverage) of the barrier metal film decreases, a void (cavity) is generated between the insulating film and the barrier metal film, and reliability of the Cu wiring is lowered.

Meanwhile, if the barrier metal film is formed of only Ta, adhesion with the Cu wiring is low, and a coverage of the Cu is lowered. For this reason, a void may be generated between the Cu wiring and the barrier metal film, and reliability of the Cu wiring is lowered. Further, alloying of Cu due to Ti diffusion does not occur, and the reliability of the Cu wiring cannot be improved.

For this reason, in the minute wiring, it is difficult to reduce an increase in the wire resistance of the Cu wiring and improve reliability of the Cu wiring.

### SUMMARY

In one embodiment, there is provided a semiconductor device. The semiconductor device includes an insulating film; a trench which is formed in the insulating film; a barrier metal film which is formed on a sidewall and a bottom surface of the trench, and is composed of an alloy of titanium and tantalum; and a copper wiring which is stacked on the barrier metal film, and is located in the trench. In this case, a titanium concentration of the barrier metal film is equal to or more than 0.1 at % and equal to or less than 14 at %.

In another embodiment, there is provided a method of manufacturing a semiconductor device. The method includes a process of forming an insulating film on a semiconductor substrate; a process of forming a trench in the insulating film; a process of forming a barrier metal film, which is composed of an alloy of titanium and tantalum, on each of a side surface and a bottom surface of the trench; and a process of embedding a copper film in the trench. In this case, a titanium concentration of the barrier metal film is equal to or more than 0.1 at % and equal to or less than 14 at %.

In another embodiment, there is provided a target of a sputtering device to form a barrier metal film on a copper wiring. In this case, the target is composed of tantalum and titanium, and contains the titanium whose concentration is equal to or more than 0.1 at % and equal to or less than 14 at %.

According to the embodiments of the present invention, since the Ti concentration of the barrier metal film that is composed of an alloy of tantalum and titanium is set to be equal to or more than 0.1 at % and equal to or less than 14 at %, the titanium can be suppressed from excessively diffusing into the copper wiring due to a thermal history. As a result, it is possible to prevent wire resistance of the copper wiring from increasing. Further, because the titanium concentration is set as described above, the copper wiring and the barrier metal film can be securely bonded to each other, and reliability of the copper wiring can be improved by preventing a void from being generated between the copper wiring and the barrier metal film. Further, alloying occurs by Ti in the Cu wiring, and reliability is improved. Accordingly, it is possible to reduce an increase in wire resistance of the copper wiring and improve reliability of the copper wiring.

According to the embodiments of the present invention described above, it is possible to reduce an increase in wire resistance of the copper wiring and improve reliability of the copper wiring.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A to 1D show a method of manufacturing a semiconductor device according to an embodiment of the present invention;

FIG. 2 shows a semiconductor device according to an embodiment of the present invention; and

FIG. 3 shows a result of wire resistance of a copper wiring.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereinafter, the preferred embodiment of the present invention will be described in detail with reference to the accompanying drawings. In all drawings, structural elements that have substantially the same function and structure will be denoted by the same reference numerals, and the description of these structural elements will not be repeated.

### First Embodiment

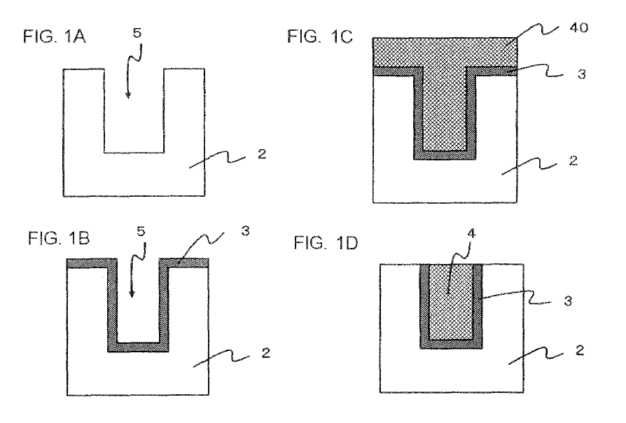

FIGS. 1A to 1D are cross-sectional views showing a method of manufacturing a semiconductor device according to this embodiment. The semiconductor device according to this embodiment includes an insulating film 2, a barrier metal film 3 that includes a trench formed in the insulating film 2 and an alloy of titanium (Ti) and tantalum (Ta), which is formed on a sidewall and a bottom surface of the trench, and a copper (Cu) wiring 4 that is stacked on the barrier metal film 3 and located in the trench, as shown in FIG. 1D. A Ti concentration of the barrier metal film 3 is equal to or more than 0.1 at % and equal to or less than 14 at %.

The method of manufacturing a semiconductor device according to this embodiment will be described using FIGS. 1A to 1D. First, as shown in FIG. 1A, a trench 5 is formed in a surface of the insulating film 2. At this time, as the trench 5, only a wiring trench may be formed or both a via hole and the wiring trench may be formed. If the via hole and the wiring trench are formed, an wiring and a plug can be simultaneously formed. In this case, any one of a via first method, a trench first method, a middle first method, and a dual hard mask method may be used.

The insulating film 2 is a low dielectric constant film (so-called Low-k film) whose relative dielectric constant is equal to or less than 3.0. As the insulating film 2, polyhydrogensiloxane, such as SiOC, HSQ (hydrogen silsesquioxane), MSQ (methyl silsesquioxane), or MHSQ (methylated hydrogen silsesquioxane), organic materials containing aromatic series, such as polyarylether (PAE), divinylsiloxane-bis-benzocyclobutene (BCB) or Silk (registered trademark), an SOG, a FOX (flowable oxide) Cytop, or BCB (benzocyclobutene) may be used. Further, as the insulating film 2, a film (porous film) where a plurality of pores are formed in the insulting film may be used.

Next, as shown in FIG. 1B, in order to cover the side surface and the bottom surface of the trench 5, the barrier metal film 3 is formed. At this time, the barrier metal film 3 is deposited on the insulating film 2 using a sputtering method.

In this case, when the barrier metal film 3 is formed using the sputtering method, a target that is composed of two components of Ta and Ti is used as a target of a sputtering device. The target contains Ti whose concentration is equal to or more than 0.1 at % and equal to or less than 14 at %. More preferably, a Ti concentration in the target is equal to or more than 3 at % and equal to or less than 10 at %.

Next, as shown in FIG. 1C, a Cu film 40 is formed in the trench 5 and on the insulating film 2. In this case, the Cu film 40 is formed using a sputtering method and a plating method, and stacked on the barrier metal film 3.

Next, a thermal treatment is performed on the barrier metal film 3 and the Cu film 40. At this time, the thermal treatment temperature is equal to or higher than 250° C. and equal to or lower than 400° C., and preferably equal to or higher than 250° C. and equal to or lower than 350° C. However, the thermal treatment temperature may be equal to or higher than 350° C. and equal to or lower than 400° C. The thermal treatment time is 30 seconds to one hour. By the thermal treatment, Ti that is contained in the barrier metal film 3 diffuses into the Cu film 40, and Ti is segregated at an interface between the Cu film 40 and the barrier metal film 3. By the segregated Ti, adhesion between the Cu film and the barrier metal film is improved. A ratio between Ti and Ta in the obtained barrier metal film 3 is almost equal to a ratio between Ti and Ta that are contained in the above target.

Next, as shown in FIG. 1D, the Cu film 40 and the barrier metal film 3 that are located on the insulating film 2 are removed by CMP (Chemical Mechanical Polishing), thereby completing the Cu wiring 4.

Next, the functions and effects of this embodiment will be described. In the semiconductor device according to this embodiment, since a Ti concentration of the barrier metal film 3 that is composed of an alloy of Ta and Ti is set to be equal to or less than 14 at %, Ti can be suppressed from excessively diffusing into the Cu wiring 4 due to a thermal history. As a result, it is possible to prevent wire resistance of the Cu wiring 4 from increasing. Meanwhile, if the Ti concentration is set to be equal to or more than 0.1 at %, the Cu wiring 4 and the barrier metal film 3 can be securely bonded to each other, and reliability of the Cu wiring 4 can be improved by preventing a void from being generated between the Cu wiring 4 and the barrier metal film 3. Further, alloying occurs by Ti in the Cu wiring 4, and reliability is improved. Accordingly, it is possible to reduce an increase in wire resistance of the Cu wiring 4 and improve reliability of the Cu wiring 4.

### Second Embodiment

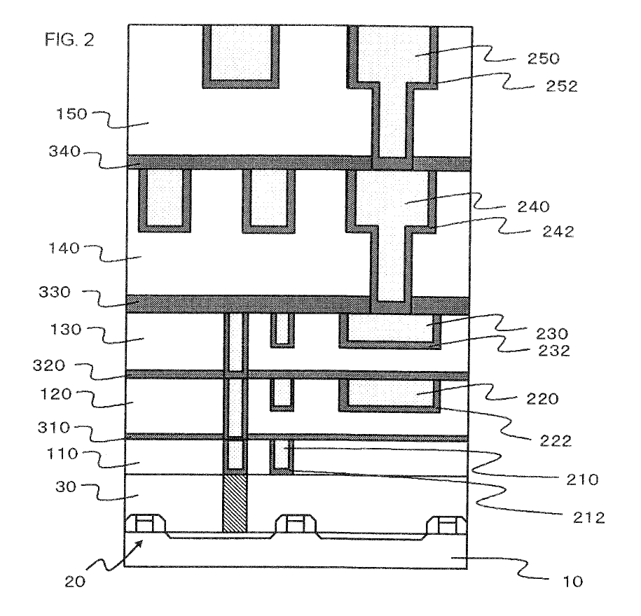

FIG. 2 is a cross-sectional view illustrating the configuration of a semiconductor device according to a second embodiment. The semiconductor device has the configuration where an insulating interlayer 30 and an insulating layer 110 are formed on a substrate 10 having a transistor 20 formed thereon, and insulating layers 120, 130, 140, and 150 are stacked in this order.

The substrate 10 is, for example, a silicon substrate. The insulating layer 110 has the same configuration as the insulating film 2 in the first embodiment. In the insulating layer 110, a Cu wiring 210 is embedded. The Cu wiring 210 has the same configuration as the Cu wiring 4 in the first embodiment. The Cu wiring 210 is connected to the transistor 20 through a contact that is embedded in the insulating interlayer 30. The insulating interlayer 30 is made of, for example, silicon oxide.

The insulating layers 120, 130, 140, and 150 have the same configuration as the insulating film 2 in the first embodiment. In the insulating layers 120, 130, 140, and 150, Cu wirings 220, 230, 240, and 250 are buried, respectively. The Cu wirings 220, 230, 240, and 250 have the same configurations as the Cu wiring 4 in the first embodiment, and are formed by using the same method as the Cu wiring 4. Between the Cu wirings 220, 230, 240, and 250 and the insulating layers 120, 130, 140, and 150, barrier metal films 212, 222, 232, 242, and 252 that have the same on figuration as the barrier metal film 3 in the first embodiment are provided. A ratio of Ti and Ta in the barrier metal films 212, 222, 232, 242, and 252 is almost equal to the ratio of Ti and Ta that are contained in the target used when the barrier metal film is deposited.

Further, a diffusion barrier 310 is formed between the insulating layer 110 and the insulating layer 120. In the same way, diffusion barriers 320, 330, and 340 are formed between the insulating layer 120 and the insulating layer 130, between the insulating layer 130 and the insulating layer 140, and the insulating layer 140 and the insulating layer 150, respectively. The diffusion barriers 320, 330, and 340 are formed of, for example, SiCN, SiC, or SiN.

Even in this embodiment, the same effect as the first embodiment can be obtained.

The embodiments of the present invention have been described with reference to the accompanying drawings, but the present invention is not limited thereto. Various configurations other than the above configuration may be used. For example, in the embodiments, the thermal treatment of the barrier metal film and the Cu film is performed between the process of forming the Cu film and the process of performing the CMP. However, the thermal treatment of the barrier metal film and the Cu film may be performed in the process of manufacturing a semiconductor device. Even in this case, the ratio of Ti and Ta in the barrier metal film becomes substantially equal to the ratio of Ti and Ta that are contained in the target used when the barrier metal film is deposited.

### EXAMPLE

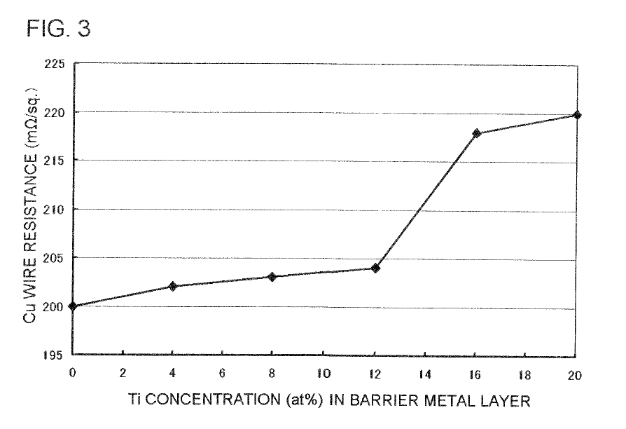

In the method that is described in the first embodiment, the Cu wiring 4 is prepared in which the ratio of Ti in the barrier metal film 3 is varied, and effective resistance of the Cu wiring 4 is measured. The measured result is shown in FIG. 3. The ratio of Ti is set to 0, 4, 8, 12, 16, or 20 at %. The thermal treatment temperature is 350° C.

As shown in FIG. 3, by lowering the ratio of Ti in the barrier metal film 3 from 16 at % to 12 at %, the resistance of the Cu wiring 4 could be reduced from 218 (mΩ/square) to 204 (mΩ/square).

According to the result of an adhesion test of the barrier metal film 3 and the Cu wiring 4, by setting the ratio of Ti in the barrier metal film 3 equal to or more than 0.1 at %, superior adhesion could be obtained. By setting the ratio of Ti in the barrier metal film 3 equal to or more than 3 at %, adhesion was further improved.

According to the result of investigating a barrier property of Cu of the barrier metal film 3, by setting the ratio of Ti in the barrier metal film 3 equal to or more than 0.1 at % and equal to or less than 14 at %, a superior barrier property was obtained. Further, by setting the ratio of Ti in the barrier metal film 3 equal to or more than 0.1 at % and equal to or less than 10 at %, a barrier property could be further improved.

It is apparent that the present invention is riot limited to the above embodiment, and may be modified and changed without departing from the scope and spirit of the invention.

What is claimed is:

1. A semiconductor device comprising:
an insulating film;
a trench which is formed in the insulating film;
a barrier metal film which is formed on a sidewall and a bottom surface of- the trench, and is composed of an alloy of titanium and tantalum; and
a copper wiring that is stacked on the barrier metal film, and is located in the trench,
wherein a titanium concentration of the barrier metal film is equal to or more than 0.1 at % and equal to or less than 14 at %.

2. The semiconductor device according to claim 1,
wherein the titanium concentration of the barrier metal film is equal to or more than 0.1 at % and equal to or less than 10 at %.

3. A method of manufacturing a semiconductor device, comprising:
forming an insulating film on a semiconductor substrate;
forming a trench in the insulating film;
forming a barrier metal film, which is composed of an alloy of titanium and tantalum, on each of a side surface and a bottom surface of the trench; and
embedding a copper film in the trench,
wherein a titanium concentration of the barrier metal film is equal to or more than 0.1 at % and equal to or less than 14 at %.

4. The method according to claim 3, wherein the titanium concentration of the barrier metal film is equal to or more than 0.1 at % and equal to or less than 10 at %.

5. The method according to claim 3, further comprising performing a thermal treatment on the barrier metal film after the embedding of the copper film in the trench.

6. The method according to claim 5, wherein the thermal treatment is performed at the temperature that is equal to or higher than 250° C. and equal to or lower than 400° C.

7. A target of a sputtering device to form a barrier metal film on a copper wiring, wherein the target is composed of tantalum and titanium, and contains the titanium whose concentration is equal to or more than 0.1 at % and equal to or less than 14 at %.
